(19) United States
(12) Patent Application Publication
(10) Pub. No.: US 2026/0114231 A1
(43) Pub. Date: Apr. 23, 2026

(54) MEMBER FOR SEMICONDUCTOR MANUFACTURING APPARATUS

(71) Applicant: NGK INSULATORS, LTD., Nagoya-shi (JP)

(72) Inventors: Taro USAMI, Ginan-town (JP); Tatsuya KUNO, Nagoya-shi (JP); Natsuki HIRATA, Nagoya-shi (JP); Naoki YAMAMOTO, Handa-shi (JP)

(21) Appl. No.: 19/424,386

(22) Filed: Dec. 18, 2025

Related U.S. Application Data
(63) Continuation of application No. PCT/JP2025/017842, filed on May 16, 2025.

(30) Foreign Application Priority Data
Jul. 3, 2024 (JP) 2024-107427

(51) Int. Cl. H10P 72/72; H01J 37/32

(52) U.S. Cl. CPC H10P 72/722; H01J 37/32715; H01J 2237/2007

(57) ABSTRACT

A member for a semiconductor manufacturing apparatus includes: a ceramic plate having on its upper surface at least one of a wafer placement surface or a focus-ring placement surface; a plug-receiving hole penetrating the ceramic plate in an up-down direction and having a tapered inner peripheral surface whose lower side narrows; and a plug fitted in the plug-receiving hole, the plug having a tapered outer peripheral surface whose lower side narrows and allowing gas to flow in the up-down direction; wherein an outer peripheral surface of the plug is steeper than an inner peripheral surface of the plug-receiving hole.

### CROSS-REFERENCE TO RELATED APPLICATION

This application is a continuation application of PCT/JP2025/017842, filed on May 16, 2025, which claims the benefit of priority from Japanese Patent Application No. 2024-107427, filed on Jul. 3, 2024, the entire contents of which are incorporated herein by reference.

### BACKGROUND OF THE INVENTION

### 1. Field of the Invention

The present invention relates to a member for a semiconductor manufacturing apparatus.

### 2. Description of the Related Art

A member for a semiconductor manufacturing apparatus having a ceramic plate provided with a wafer placement surface on its upper surface have been conventionally used in a semiconductor manufacturing apparatus. For example, the member for a semiconductor manufacturing apparatus disclosed in PTL 1 includes a plug-receiving hole penetrating a ceramic plate in an up-down direction, and a plug disposed in the plug-receiving hole and allowing gas to flow in the up-down direction. The plug has, for example, an inverted frustoconical shape in which the top is larger than the bottom, and is disposed in a plug-receiving hole having the same shape.

### CITATION LIST

### Patent Literature

PTL 1: WO 2023/153021 pamphlet (FIG. 13 and paragraph [0041])

### SUMMARY OF THE INVENTION

However, in the above-described member for a semiconductor manufacturing apparatus, since the plug-receiving hole has an inverted frustoconical shape the same as that of the plug, the plug may come off the member for a semiconductor manufacturing apparatus during production, transportation, use, and the like.

The present invention has been made to solve such a problem, and its principal object is to suppress plug drop-out.
[1] A member for a semiconductor manufacturing apparatus of the present invention includes: a ceramic plate having on its upper surface at least one of a wafer placement surface or a focus-ring placement surface; a plug-receiving hole penetrating the ceramic plate in an up-down direction and having a tapered inner peripheral surface whose lower side narrows; and a plug fitted in the plug-receiving hole, the plug having a tapered outer peripheral surface whose lower side narrows and allowing gas to flow in the up-down direction; wherein an outer peripheral surface of the plug is steeper than an inner peripheral surface of the plug-receiving hole.

In this member for a semiconductor manufacturing apparatus, the plug having the tapered outer peripheral surface whose lower side narrows is fitted in the plug-receiving hole having the tapered inner peripheral surface whose lower side narrows, and the outer peripheral surface of the plug is steeper than the inner peripheral surface of the plug-receiving hole. Therefore, plug drop-out can be suppressed. The reason for this suppression is considered to be, for example, as follows. That is, since the outer peripheral surface of the plug is steeper than the inner peripheral surface of the plug-receiving hole, the plug is considered to be mainly fitted into a lower, more narrowed portion of the plug-receiving hole. In that portion the ceramic plate is thinner and undergoes an appropriate deformation, so the plug can be held with strong fitting strength, thereby suppressing plug drop-out.

In this specification, up and down, left and right, and front and back, for example, are used to describe the present invention, but up and down, left and right, and front and back represent only a relative positional relationship. Thus, when the orientation of the member for a semiconductor manufacturing apparatus is changed, up and down may become left and right, or left and right may become up and down. Such cases are also included in the technical scope of the present invention.
[2] In the above member for a semiconductor manufacturing apparatus (the member for a semiconductor manufacturing apparatus described in [1] above), a difference between an inclination angle α of the outer peripheral surface of the plug and an inclination angle θ of the inner peripheral surface of the plug-receiving hole may be 0.2° or less. When this difference is 0.2° or less, a gap between the outer peripheral surface of the plug and the inner peripheral surface of the plug-receiving hole can be reduced. In this specification, the inclination angle α of the outer peripheral surface of the plug is defined as an angle (0°<π<90°) between a plane perpendicular to the axis of the plug and the outer peripheral surface of the plug. The inclination angle θ of the inner peripheral surface of the plug-receiving hole is defined as an angle (0°<θ<90°) between a plane perpendicular to the axis of the plug-receiving hole and the inner peripheral surface of the plug-receiving hole.
[3] In the above member for a semiconductor manufacturing apparatus (the member for a semiconductor manufacturing apparatus described in [1] or [2] above), the difference between the inclination angle α of the outer peripheral surface of the plug and the inclination angle θ of the inner peripheral surface of the plug-receiving hole may be 0.05° or more and 0.10° or less. When this difference is 0.05° or more, plug drop-out can be further suppressed. When this difference is 0.10° or less, a gap between the plug and the ceramic plate can be further reduced.
[4] In the above member for a semiconductor manufacturing apparatus (the member for a semiconductor manufacturing apparatus described in any one of [1] to [3] above), the inclination angle θ of the inner peripheral surface of the plug-receiving hole may be 70° or more and less than 88°.
[5] In the above member for a semiconductor manufacturing apparatus (the member for a semiconductor manufacturing apparatus described in any one of [1] to [4] above), an extraction strength required to pull the plug out toward the wafer placement surface side may be 150 N or more. The larger the extraction strength, the less likely plug drop-out will occur.
[6] The above member for a semiconductor manufacturing apparatus (the member for a semiconductor manufacturing apparatus described in any one of [1] to [5] above) may further comprise a conductive base plate bonded to a lower surface of the ceramic plate and provided with a gas supply passage communicating with the plug-receiving hole. The conductive base plate may be used, for example, as a cooling plate for cooling the ceramic plate, or as a radio-frequency (RF) electrode for generating plasma above the wafer placement surface.
[7] In the above member for a semiconductor manufacturing apparatus (the member for a semiconductor manufacturing apparatus described in any one of [1] to [6] above), the ceramic plate may have an embedded electrode. The electrode may be, for example, an electrostatic electrode, a heater electrode (resistive heating element), or an RF electrode.

### BRIEF DESCRIPTION OF THE DRAWINGS

FIG. 1 is a longitudinal sectional view of a wafer placement table 10 as an example of the member for a semiconductor manufacturing apparatus according to the present invention.

FIG. 2 is a plan view of a ceramic plate 20.

FIG. 3 is a partially enlarged view of FIG. 1.

FIGS. 4A to 4C are process diagrams illustrating a method of manufacturing the wafer placement table 10.

FIG. 5 is an explanatory view showing an example of a method for measuring punching strength.

FIG. 6 is a partially enlarged view of a wafer placement table 110.

FIG. 7 is a partially enlarged view of a wafer placement table 210.

FIGS. 8A and 8B are explanatory views of a plug 350.

FIGS. 9A to 9C are explanatory views of a plug 450.

FIG. 10 is a longitudinal sectional view of a wafer placement table 510.

FIG. 11 is an explanatory view showing the relationship between press-fit strength and punching strength.

### DETAILED DESCRIPTION OF THE INVENTION

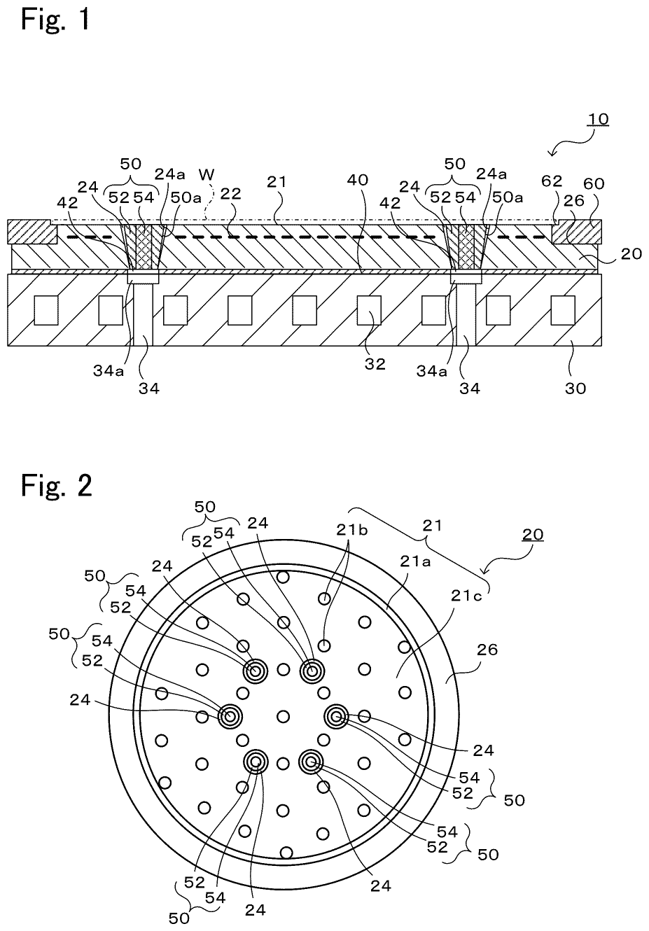

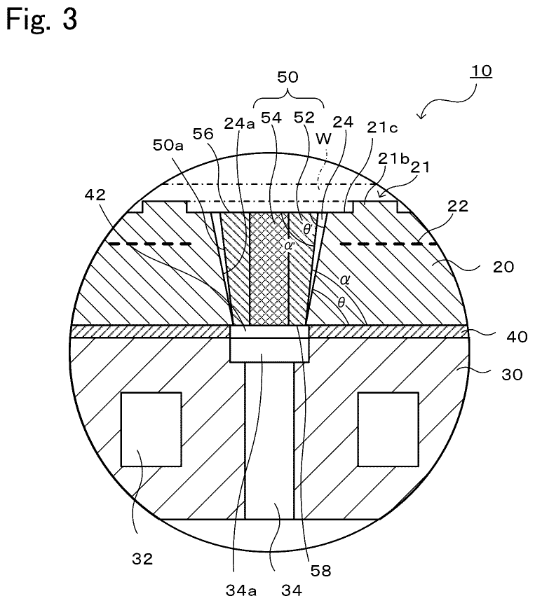

Preferred embodiments of the present invention will be described with reference to the drawings. FIG. 1 is a longitudinal sectional view of a wafer placement table 10 as an example of the member for a semiconductor manufacturing apparatus according to the present invention; FIG. 2 is a plan view of a ceramic plate 20; and FIG. 3 is a partially enlarged view of FIG. 1.

The wafer placement table 10 includes a ceramic plate 20, a plug-receiving hole 24, a base plate (conductive base plate) 30, a metal bonding layer 40, and a plug 50.

The ceramic plate 20 is a ceramic disk, such as an alumina sintered body or an aluminum nitride sintered body (for example, a diameter of 300 mm). The ceramic plate 20 is preferably dense. “Dense” herein means a porosity of 5% or less (preferably 3% or less, more preferably 1% or less). The porosity of the ceramic plate 20 is an open porosity measured in accordance with JIS R1634:1998. The thickness of the ceramic plate 20 is, for example, 1 mm or more and 5 mm or less. The ceramic plate 20 has, on its upper surface, a wafer placement surface 21 and a focus-ring (FR) placement surface 26. The wafer placement surface 21 is a circular surface on which a wafer W is placed. As shown in FIG. 2, a seal band 21a is formed along an outer edge of the wafer placement surface 21, and a plurality of circular small projections 21b are formed over the whole surface. The seal band 21a and the circular small projections 21b have the same height, which is, for example, several micrometers to several tens of micrometers. A portion of the wafer placement surface 21 where no seal band 21a or circular small projections 21b are provided is referred to as a reference surface 21c. The FR placement surface 26 is an annular surface provided around the wafer placement surface 21. The height of the FR placement surface 26 is one step lower than the height of the wafer placement surface 21. An annular focus ring 60 is placed on the FR placement surface 26. The focus ring 60 is formed, for example, of Si. An annular groove 62 is provided above an inner side surface of the focus ring 60 so as not to contact the wafer W. An outer diameter of the focus ring 60 is larger than an outer diameter of the ceramic plate 20. Therefore, the focus ring 60 is placed on the FR placement surface 26 in an overhanging state projecting outward from the wafer placement table 10. The ceramic plate 20 has an embedded electrode 22. The electrode 22 is a planar mesh electrode used as an electrostatic electrode, to which a DC voltage can be applied. When a DC voltage is applied to the electrode 22, the wafer W is attracted and fixed to the wafer placement surface 21 (specifically, to the upper surfaces of the seal band 21a and the circular small projections 21b) by electrostatic attraction; and when the application of the DC voltage is canceled, the attraction and fixation of the wafer W to the wafer placement surface 21 are released.

The plug-receiving hole 24 is a hole penetrating the ceramic plate 20 in an up-down direction, here a through-hole extending from the lower surface of the ceramic plate 20 to the wafer placement surface 21. The plug-receiving hole 24 faces a gas hole 34 of the base plate 30. Although the plug-receiving hole 24 penetrates the electrode 22 in the up-down direction, the electrode 22 is not exposed at the inner peripheral surface of the plug-receiving hole 24. The plug-receiving hole 24 is a tapered hole having a frustoconical space whose upper opening area is larger than its lower opening area, and has a tapered inner peripheral surface 24a whose lower side narrows. An inclination angle θ (see FIG. 3) of the inner peripheral surface 24a of the plug-receiving hole 24 is, for example, 70° or more and less than 88°, preferably 75° or more and 87° or less. As shown in FIG. 2, the plug-receiving holes 24 are provided at a plurality of locations (for example, a plurality of locations arranged at equal intervals in the circumferential direction) so as to open to the wafer placement surface 21 of the ceramic plate 20. Diameters of the upper and lower openings of the plug-receiving hole 24 are each, for example, 1 mm or more and 5 mm or less.

The base plate 30 is a conductive disk having good thermal conductivity (a disk having the same diameter as or a larger diameter than the ceramic plate 20). Inside the base plate 30, a refrigerant flow path 32 through which a refrigerant (for example, an electrically insulating liquid such as a fluorinated inert liquid) circulates and a gas hole 34 for supplying gas to the plug 50 are formed. The gas hole 34 is provided to penetrate the base plate 30 in the up-down direction and has a large-diameter portion 34a on its upper side. In plan view, the large-diameter portion 34a encompasses the lower opening of the plug-receiving hole 24. The refrigerant flow path 32 is formed in a manner of a one-stroke pattern from an inlet to an outlet over the entire surface of the base plate 30 in plan view. Examples of the material for the base plate 30 include metals and composite materials. Examples of the metals include Mo. Examples of the composite materials include a metal-ceramic composite material. Examples of the metal-ceramic composite material include metal matrix composite materials (MMCs) and ceramic matrix composite materials (CMCs). Specific examples of these composite materials include materials containing Si, SiC, and Ti, and materials prepared by impregnating SiC porous bodies with Al and/or Si. The material containing Si, SiC, and Ti is referred to as SiSiCTi. The material prepared by impregnating a SiC porous body with Al is referred to as AlSiC, and the material prepared by impregnating a SiC porous body with Si is referred to as SiSiC. The material for the base plate 30 is preferably a material having a coefficient of thermal expansion close to that of the material for the ceramic plate 20. The base plate 30 is also used as an RF electrode. Specifically, an upper electrode (not shown) is disposed above the wafer placement surface 21, and plasma is generated by applying RF power between the parallel plate electrodes constituted by the upper electrode and the base plate 30.

The metal bonding layer 40 bonds the lower surface of the ceramic plate 20 and the upper surface of the base plate 30 to each other. The metal joint layer 40 is formed, for example, by TCB (thermal compression bonding). The TCB is a well-known method in which a metallic joint member is held between two members to be joined together and the two members are heated to a temperature equal to or lower than the solidus temperature of the metallic joint member to pressure-bond the two members together. The metal bonding layer 40 may be a layer formed of solder or a metal brazing material. The metal bonding layer 40 has a through hole 42. The through-hole 42 is provided at a position facing the large-diameter portion 34a of the gas hole 34. The through-hole 42 is coaxial with the large-diameter portion 34a, and a diameter of the through-hole 42 coincides with a diameter of the large-diameter portion 34a. As used herein, “coaxial” includes substantially coaxial cases (e.g., within tolerances) as well as perfectly coaxial cases; and “coincide” includes substantially coincident cases (e.g., within tolerances) as well as perfectly coincident cases (the same applies below).

The plug 50 is disposed and fitted in the plug-receiving hole 24 so as to be coaxial with the plug-receiving hole 24. The plug 50 is an electrically insulating member that allows gas to flow in the up-down direction. Here, the plug 50 is a member made of a ceramic such as alumina or aluminum nitride, for example the same material as the ceramic plate 20. The plug 50 has a dense portion 52 that is dense and a porous ventilation portion 54 penetrating the dense portion 52 in the up-down direction. “Dense” means a porosity of 5% or less (preferably 3% or less, more preferably 1% or less). The porosity of the dense portion of the plug 50 is determined as follows. An observation is made with an SEM (scanning electron microscope) at a magnification of 3000×, and using the brightness distribution of the obtained SEM image, binarization into object portions and pore portions is carried out by Otsu's thresholding method. The area ratio of the pore portions to the whole is calculated as the porosity. The ventilation portion 54 is formed, for example, of a porous body made of the same material as the dense portion 52. “Porous” means a porosity of greater than 5% and less than 100%. The ventilation portion 54 preferably has a porosity of 30% or more and an average pore diameter of 20 μm or more. The porosity and pore size of the porous portion of the plug 50 are measured by mercury intrusion porosimetry (JIS R1655:2003). The plug 50 is a frustoconical member whose upper surface 56 (see FIG. 3) has a larger area than its lower surface 58 (see FIG. 3), and has a tapered outer peripheral surface 50a whose lower side narrows. The outer peripheral surface 50a of the plug 50 is steeper than the inner peripheral surface 24a of the plug-receiving hole 24. That is, an inclination angle α (see FIG. 3) of the outer peripheral surface 50a of the plug 50 is larger than an inclination angle θ of the inner peripheral surface 24a of the plug-receiving hole 24. A difference (α-θ) between the inclination angle α of the outer peripheral surface 50a of the plug 50 and the inclination angle θ of the inner peripheral surface 24a of the plug-receiving hole 24 is, for example, 0.2° or less, or 0.03° or more and 0.15° or less, or 0.05° or more and 0.10° or less. The upper surface 56 of the plug 50 is exposed at the upper opening of the plug-receiving hole 24 and is disposed in the same plane as the reference surface 21c. As used herein, “same” includes substantially the same (e.g., within tolerances) as well as perfectly the same (the same applies below). The plug 50 and the plug-receiving hole 24 are designed in advance so that, when the plug 50 is inserted into the plug-receiving hole 24 and press-fitted at a predetermined press-fit strength, a height of the upper surface 56 of the plug 50 coincides with a height of the reference surface 21c of the ceramic plate 20. Therefore, the upper surface 56 of the plug 50 and the reference surface 21c of the ceramic plate 20 can be readily arranged in the same plane. A height of the lower surface 58 of the plug 50 may be the same as, higher than, or lower than a height of the lower surface of the ceramic plate 20.

Next, an example of use of the wafer placement table 10 thus configured will be described. First, with the wafer placement table 10 installed in an unillustrated chamber, the wafer W is placed on the wafer placement surface 21. Then, the interior of the chamber is depressurized with a vacuum pump to a predetermined vacuum degree, a DC voltage is applied to the electrode 22 of the ceramic plate 20 to generate electrostatic attraction, and the wafer W is attracted and fixed to the wafer placement surface 21 (specifically, to the upper surfaces of the seal band 21a and the circular small projections 21b). Next, the interior of the chamber is set to a reactive gas atmosphere at a predetermined pressure (for example, several tens to several hundreds of Pa). In this state, an RF voltage is applied between an unillustrated upper electrode provided at a ceiling portion of the chamber and the base plate 30 of the wafer placement table 10 to generate plasma. A surface of the wafer W is processed by the generated plasma. A refrigerant is circulated through the refrigerant flow path 32 of the base plate 30. Backside gas is introduced into the gas hole 34 from an unillustrated gas cylinder. As the backside gas, a heat-conductive gas (e.g., helium) is used. The backside gas is supplied and sealed into a space between a back surface of the wafer W and the reference surface 21c of the wafer placement surface 21 via the gas hole 34, the through-hole 42, and the plug 50. Due to the presence of this backside gas, heat conduction between the wafer W and the ceramic plate 20 is efficiently performed. In addition, by virtue of the presence of the electrically insulating plug 50 disposed in the plug-receiving hole 24, a creepage distance between the wafer W and the base plate 30 increases and the like, thereby suppressing discharge within the plug-receiving hole 24.

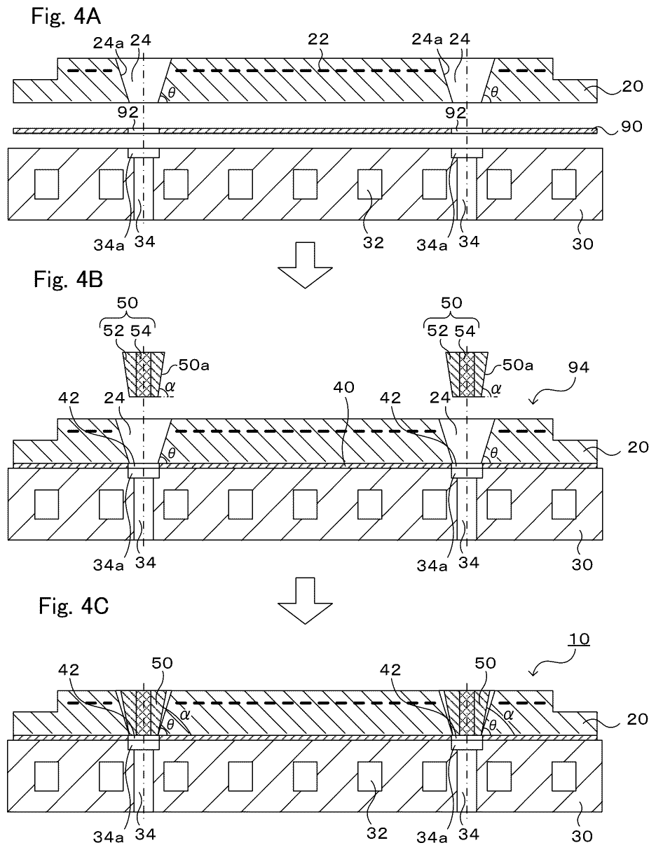

Next, an example of manufacturing the wafer placement table 10 will be described with reference to FIGS. 4A to 4C, which is a process diagram illustrating a method of manufacturing the wafer placement table 10. First, a ceramic plate 20, a base plate 30, and a metal bonding material 90 are prepared (FIG. 4A). The ceramic plate 20 has an embedded electrode 22 and is provided with a plug-receiving hole 24. The plug-receiving hole 24 has a tapered inner peripheral surface 24a whose lower side narrows. An inclination angle θ of the inner peripheral surface 24a of the plug-receiving hole 24 is, for example, 70° or more and less than 88°. The base plate 30 is provided with a refrigerant flow path 32 and a gas hole 34. The gas hole 34 has a large-diameter portion 34a on its upper side. The metal bonding material 90 has a through-hole 92 at a position facing the large-diameter portion 34a of the gas hole 34.

Subsequently, a laminate body is formed by sandwiching the metal bonding material 90 between the lower surface of the ceramic plate 20 and the upper surface of the base plate 30. At this time, lamination is performed so that the plug-receiving hole 24 of the ceramic plate 20, the through-hole 92 of the metal bonding material 90, and the gas hole 34 of the base plate 30 are coaxial. Then, the laminate body is pressure-bonded at a temperature at or below the solidus temperature of the metal bonding material 90 (for example, at a temperature from the solidus temperature minus 20° C. to the solidus temperature), and thereafter returned to room temperature (TCB). Thus, the metal bonding material 90 and the through-hole 92 become the metal bonding layer 40 and the through-hole 42, respectively, and a bonded body 94 is obtained in which the ceramic plate 20 and the base plate 30 are bonded by the metal bonding layer 40 (FIG. 4B). As the metal bonding material 90, an Al—Mg bonding material or an Al—Si—Mg bonding material can be used. Preferably, the metal bonding material 90 has a thickness of around 100 μm.

Next, a frustoconical plug 50 is prepared (FIG. 4B). The plug 50 has a dense portion 52 that is dense and a porous ventilation portion 54 penetrating the dense portion 52 in the up-down direction. The plug 50 has a tapered outer peripheral surface 50a whose lower side narrows, and an inclination angle α of the outer peripheral surface 50a is larger than an inclination angle θ of the inner peripheral surface 24a of the plug-receiving hole 24. The plug 50 is configured so that, within a predetermined range on the lower end side (for example, at least a range of 0.2 mm from the lower end), an outer diameter of the plug 50 is slightly (for example, by 20 μm or less) larger than an inner diameter at a corresponding position of the plug-receiving hole 24 (a position at the same height when the plug 50 is fitted in the plug-receiving hole 24). A height of the plug 50 is, for example, the same as a height of the plug-receiving hole 24 (i.e., a height of the ceramic plate 20). Then, the plug 50 is press-fitted into the plug-receiving hole 24 at a predetermined press-fit strength (a load applied to the plug 50 during press-fitting) (FIG. 4C). The press-fit strength is, for example, 100 N or more and 700 N or less. By press-fitting, a lower portion around the inner peripheral surface 24a of the plug-receiving hole 24, in particular, of the ceramic plate 20, and a lower portion around the outer peripheral surface 50a of the plug 50, in particular, are deformed. With such deformation of the ceramic plate 20 and the plug 50, the plug 50 is fitted in the plug-receiving hole 24. In a lower portion of the plug 50 and the plug-receiving hole 24, the outer peripheral surface 50a of the plug 50 comes into contact with the inner peripheral surface 24a of the plug-receiving hole 24 by the press-fitting, and the inclination angles α and θ become the same; however, it suffices that, at least before press-fitting, the inclination angle α is larger than the inclination angle θ. In an upper portion of the plug 50 and an upper portion of the ceramic plate 20, deformation due to press-fitting is considered to be small; therefore, when the inclination angles α and θ and an angle difference α-θ are to be determined in the press-fitted state, an inclination angle α′ (see FIG. 3), which is vertically opposite to the inclination angle α, may be regarded as the inclination angle α, and an inclination angle θ′ (see FIG. 3), which is vertically opposite to the inclination angle θ, may be regarded as the inclination angle θ. In this case, for example, the inclination angles α′ and θ′ and the angle difference α′-θ′ may be obtained by confirming, with X-ray CT, an upper-side gap between the outer peripheral surface 50a of the plug 50 and the inner peripheral surface 24a of the plug-receiving hole 24. The seal band 21a, the circular small projections 21b, and the FR placement surface 26 on the upper surface of the ceramic plate 20 may be formed before press-fitting the plug 50 into the plug-receiving hole 24, or after press-fitting the plug 50 into the plug-receiving hole 24.

Prior to the above manufacturing steps, an adjustment process may be performed in which the plug 50 is press-fitted into the plug-receiving hole 24 of the ceramic plate 20 before bonding to the base plate 30, and then the upper surface 56 of the plug 50 is aligned with the reference surface 21c of the ceramic plate 20 by machining such as polishing or grinding. After the adjustment process, the plug 50 is removed from the plug-receiving hole 24 of the ceramic plate 20 by punching or the like, and the ceramic plate 20 and the plug 50 after the adjustment are used in the above manufacturing process, thereby further improving positional accuracy of the plug 50 in the plug-receiving hole 24 (particularly positional accuracy in the up-down direction).

As described in detail above, in the wafer placement table 10, the plug 50 is fitted in the plug-receiving hole 24, and the outer peripheral surface 50a of the plug 50 is steeper than the inner peripheral surface 24a of the plug-receiving hole 24. Therefore, plug drop-out can be suppressed. The reason for the suppression is considered to be as follows, for example. Since the outer peripheral surface 50a of the plug 50 is steeper than the inner peripheral surface 24a of the plug-receiving hole 24, the plug 50 is considered to be mainly fitted into a lower, more narrowed portion of the plug-receiving hole 24. In that portion the ceramic plate 20 is thinner and undergoes an appropriate deformation, so the plug 50 can be held with strong fitting strength, thereby suppressing plug drop-out. The plug 50 is fixed in the plug-receiving hole 24 by fitting, and even without using an adhesive, the plug 50 can be fixed in the plug-receiving hole 24.

If the difference between the inclination angle α of the outer peripheral surface 50a of the plug 50 and the inclination angle θ of the inner peripheral surface 24a of the plug-receiving hole 24 is 0.2° or less, a gap between the outer peripheral surface 50a of the plug 50 and the inner peripheral surface 24a of the plug-receiving hole 24 can be reduced. If the gap between the outer peripheral surface 50a of the plug 50 and the inner peripheral surface 24a of the plug-receiving hole 24 is large, discharge may occur in the gap and alter the wafer W; by reducing this gap, discharge can be suppressed. For example, when a length of the gap in the up-down direction is 200 μm or less, discharge can be suppressed more effectively. An opening width of the gap (a radial length in plan view) may be, for example, 0.7 μm or less.

Furthermore, if the difference between the inclination angle α of the outer peripheral surface 50a of the plug 50 and the inclination angle θ of the inner peripheral surface 24a of the plug-receiving hole 24 is 0.05° or more, plug drop-out can be further suppressed. If this difference is 0.10° or less, the gap between the plug 50 and the ceramic plate 20 can be further reduced, thereby further suppressing discharge.

Furthermore, if the inclination angle θ of the inner peripheral surface 24a of the plug-receiving hole 24 is 70° or more, the opening area on the upper opening side of the plug-receiving hole 24 can be made relatively small, thereby increasing design freedom in arranging, for example, the circular small projections 21b and the electrode 22. If the inclination angle θ is less than 88°, the plug 50 can be inserted into the plug-receiving hole 24 with relative ease.

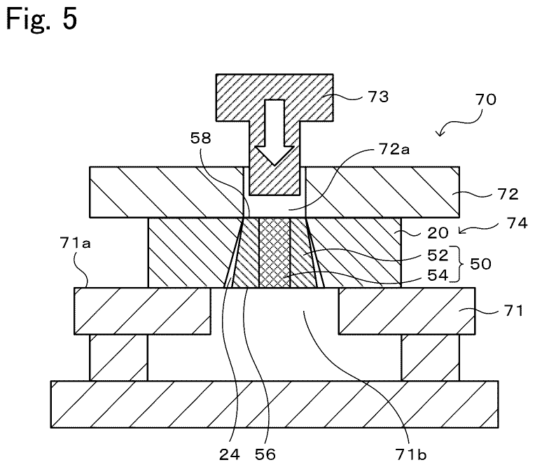

The extraction strength required to pull the plug 50 out toward the wafer placement surface 21 may be 150 N or more, or 200 N or more. The larger the extraction strength, the less likely plug drop-out will occur. The extraction strength may be 500 N or less, for example. The extraction strength may be a pull-out strength or a punching strength. The punching strength can be measured, for example, as follows. FIG. 5 illustrates an example of a method for measuring punching strength. A compression tester 70 is used. The compression tester 70 includes a base 71, a cover plate 72, and a punching pin 73 (a columnar pin with a tip diameter of 3 mm) that is movable up and down at a predetermined speed. The base 71 has a placement surface 71a on which a specimen 74 is placed, and a through-hole 71b for allowing a plug 50 punched out from the specimen 74 to fall. The cover plate 72 has an insertion hole 72a for inserting the punching pin 73 in the up-down direction. The specimen 74 is the ceramic plate 20 in which the plug 50 is disposed in the plug-receiving hole 24; the ceramic plate 20 described in the embodiment may be used as is, or may be processed for measurement. The specimen 74 is placed on the placement surface 71a of the base 71 with the lower opening of the plug-receiving hole 24 facing upward and the upper opening facing downward, and is fixed by clamping from above with the cover plate 72. At this time, the through-hole 71b of the base 71, the plug-receiving hole 24 of the specimen 74, and the insertion hole 72a of the cover plate 72 are arranged coaxially. Then, the punching pin 73 is moved downward from above the cover plate 72 at a speed of 1 mm/min to punch the plug 50 out of the specimen 74. A load during punching of the specimen 74 is continuously measured, and a maximum measured load is taken as the punching strength. As a method for measuring the pull-out strength, an appropriate method that provides results equivalent to those of the above punching strength measurement may be adopted.

Further, since the outer peripheral surface 50a (the dense portion 52) of the plug 50 is dense, cracking of the plug during fitting is less likely than in the case where the outer peripheral surface 50a is porous, and the plug can be brought into close contact with the inner peripheral surface 24a of the plug-receiving hole 24 to further increase the fitting strength. Moreover, since the ventilation portion 54 of the plug 50 is porous, an effective path length inside the ventilation portion 54 is longer than in the case of a hollow ventilation portion 54, and discharge is less likely to occur inside the ventilation portion 54.

It goes without saying that the present invention is not limited to the above embodiment and can be implemented in various modes as long as it falls within the technical scope of the present invention.

In the embodiment described above, the wafer placement surface 21 is provided with the seal band 21a and the circular small projections 21b, but the seal band 21a and the circular small projections 21b need not be provided. The wafer placement surface 21 may be, for example, a flat surface (only the reference surface 21c).

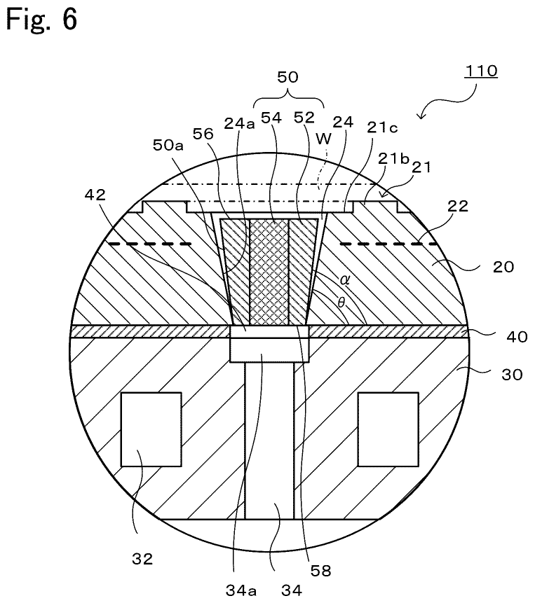

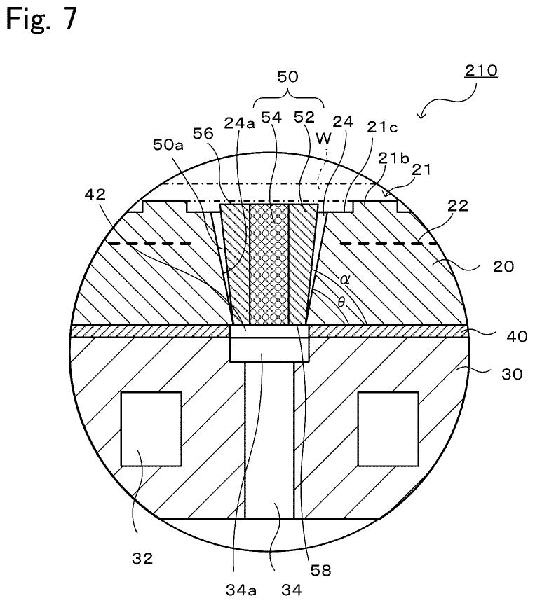

In the embodiment described above, the upper surface 56 of the plug 50 is disposed in the same plane as the reference surface 21c; however, the invention is not limited thereto. Examples are shown in FIGS. 6 and 7. In FIGS. 6 and 7, the same reference signs are given to the same components as in the above embodiment, and detailed description is omitted. As shown in FIG. 6, the upper surface 56 of the plug 50 may be formed as a recessed portion relative to the reference surface 21c. In that case, from the viewpoint of suppressing discharge inside the plug-receiving hole 24, a recess amount relative to the reference surface 21c is preferably small, e.g., 0.2 mm or less. As shown in FIG. 7, the upper surface 56 of the plug 50 may be formed as a convex portion relative to the reference surface 21c. In that case, it is preferable that the upper surface 56 of the plug 50 be positioned lower than the upper surface of the seal band 21a and the upper surfaces of the circular small projections 21b. From the viewpoint of suppressing reduction of electrostatic attraction, a protrusion amount of the convex relative to the reference surface 21c is preferably small.

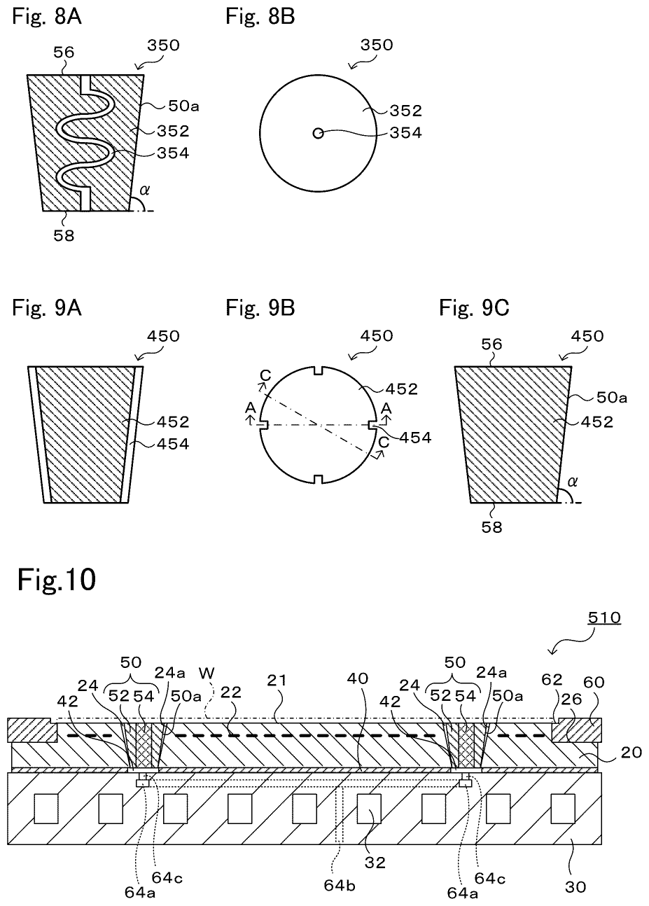

In the embodiment described above, as the plug that allows gas to flow in the up-down direction, the plug 50 having the dense portion 52 and the porous ventilation portion 54 penetrating the dense portion 52 in the up-down direction has been illustrated, but the invention is not limited thereto. For example, in place of the plug 50, a plug 350 shown in FIGS. 8A and 8B or a plug 450 shown in FIGS. 9A to 9C may be used. In FIGS. 8 and 9, the same reference signs are given to the same components as in the above embodiment, and detailed description is omitted. FIG. 8A is a longitudinal sectional view of the plug 350, and FIG. 8B is a plan view of the plug 350. Here, the plug 350 is a member made of a ceramic such as alumina or aluminum nitride, for example the same material as the ceramic plate 20. The plug 350 has a dense portion 352 and one or more (one in this example) ventilation holes 354 penetrating the dense portion 352 in the up-down direction. In FIGS. 8A and 8B, the ventilation hole 354 is shown as penetrating the dense portion 352 in a bent manner in the up-down direction; however, it may be straight or helical. At least part of the ventilation hole 354 may be porous. Two or more ventilation holes 354 may be provided. FIG. 9A is a longitudinal sectional view (sectional view taken along line A-A of FIG. 9B) of the plug 450, FIG. 9B is a plan view of the plug 450, and FIG. 9C is a sectional view taken along line C-C of FIG. 9B. Here, the plug 450 is a member made of a ceramic such as alumina or aluminum nitride, for example the same material as the ceramic plate 20. The plug 450 has a dense portion 452 and one or more (four in this example) ventilation grooves 454 formed along the outer peripheral surface 50a of the dense portion 452 from a lower end of the plug 450 to an upper end thereof. Also in this plug 450, because the outer peripheral surface 50a is steeper than the inner peripheral surface 24a of the plug-receiving hole 24 except for portions where the ventilation grooves 454 are formed, the plug 450 can be held in the plug-receiving hole 24 with strong fitting strength in the same manner as in the above embodiment, thereby suppressing plug drop-out. In FIGS. 9A to 9C, the ventilation grooves 454 are straight; however, they may be formed so as to reach from the lower end to the upper end of the plug 450 while bending, or may be helical. At least part of the ventilation grooves 454 may be porous.

In the embodiment described above, the shapes of the plug-receiving hole 24 and the plug 50 are frustoconical; however, the invention is not limited thereto. For example, the shapes of the plug-receiving hole and the plug may be truncated pyramid. In that case, “diameter(s)” of the upper and lower openings of the plug-receiving hole 24 and the “diameter(s)” of the upper and lower surfaces 56, 58 of the plug 50 should be read as “equivalent circle diameter(s) corresponding to equal area.”

In the embodiment described above, the plug 50 is an electrically insulating member, but the invention is not limited thereto. For example, the plug 50 may be a conductive member formed of a conductive ceramic. The same applies to the plugs 350 and 450. A conductive plug serves to prevent a potential gradient from occurring in the plug-receiving hole 24 of the ceramic plate 20 and thus suppresses discharge within the plug-receiving hole 24.

In the embodiment described above, the plug-receiving hole 24 is provided as a through-hole extending from the lower surface of the ceramic plate 20 to the wafer placement surface 21; however, instead of or in addition to the through-hole, a through-hole extending from the lower surface of the ceramic plate 20 to the FR placement surface 26, as a plug-receiving hole, may be provided. In that case, the through-holes extending from the lower surface of the ceramic plate 20 to the FR placement surface 26 may be provided at a plurality of locations (for example, a plurality of locations arranged at equal intervals in the circumferential direction) so as to open to the FR placement surface 26 of the ceramic plate 20.

In the embodiment described above, as an example of the member for a semiconductor manufacturing apparatus of the present invention, the wafer placement table 10 having the wafer placement surface 21 and the FR placement surface 26 has been described; however, the wafer placement table 10 need not have the FR placement surface 26. Further, the member for a semiconductor manufacturing apparatus of the present invention may be a focus-ring placement table having the FR placement surface 26 but not having a wafer placement surface.

In the embodiment described above, the electrode 22 is disposed at a position corresponding to the wafer placement surface 21; however, instead of or in addition to the electrode 22, an electrode may be disposed at a position corresponding to the FR placement surface 26.

In the embodiment described above, the electrode 22 embedded in the ceramic plate 20 has been exemplified as an electrostatic electrode; however, the invention is not limited thereto. For example, instead of or in addition to the electrode 22, a heater electrode (resistive heating element) or an RF electrode may be embedded in the ceramic plate 20.

In the embodiment described above, the ceramic plate 20 and the base plate 30 are bonded with the metal bonding layer 40; however, a resin adhesive layer may be used in place of the metal bonding layer 40.

In the embodiment described above, the base plate 30 is provided with the gas hole 34 constituting a gas supply passage; however, the invention is not limited thereto. For example, as shown in FIG. 10, the base plate 30 may be provided with a ring portion 64a concentric with the base plate 30 in plan view, an introduction portion 64b for introducing gas from a back surface of the base plate 30 to the ring portion 64a, and a distribution portion 64c for distributing gas from the ring portion 64a to the respective plugs 50. In FIG. 10, the same reference signs are given to the same components as in the above embodiment. A number of the introduction portion(s) 64b is smaller than a number of the distribution portion(s) 64c, and may be one, for example. In this way, a number of external gas pipes connected to the lower surface of the base plate 30 can be made smaller than a number of the plugs 50. Such a configuration may be adopted in the wafer placement tables 110 and 210.

In the embodiment described above, the wafer placement table 10 includes the ceramic plate 20, the plug-receiving hole 24, the base plate 30, the metal bonding layer 40, and the plug 50; however, other configurations are not limited as long as the wafer placement table 10 includes the ceramic plate 20, the plug-receiving hole 24, and the plug 50. For example, the metal bonding layer 40 and the base plate 30 need not be provided. The same applies to a focus-ring placement table.

### EXAMPLES

Hereinafter, examples in which the member for a semiconductor manufacturing apparatus of the present invention was specifically produced will be described. Experimental Examples 1 and 2 correspond to Examples of the present invention, and Experimental Example 3 corresponds to a Comparative Example.

### Experimental Example 1

A ceramic plate made of alumina and having a thickness of 3.6 mm was prepared. As a plug-receiving hole, a tapered hole was provided having an upper opening diameter of 4.1 mm and an inner peripheral surface inclination angle θ of 85.00°. A plug made of alumina and having a thickness of 3.6 mm was prepared. The plug had an outer peripheral surface inclination angle α of 85.10°, and its outer peripheral surface was dense (porosity 1.0% or less). The plug was inserted from the upper opening side of the plug-receiving hole and press-fitting was performed at one of three press-fit strengths of 100 N, 300 N, and 500 N. Five specimens were prepared for each press-fit strength, for a total of 15 specimens. For each specimen, the punching strength was measured by the above-described punching strength measurement method. An Instron universal testing machine Model 5566 was used as the compression tester.

### Experimental Example 2

The same procedure as in Experimental Example 1 was followed except that a plug having an outer peripheral surface inclination angle α of 85.05° was used.

### Experimental Example 3

The same procedure as in Experimental Example 1 was followed except that a plug having an outer peripheral surface inclination angle α of 85.00° was used.

### Experimental Results

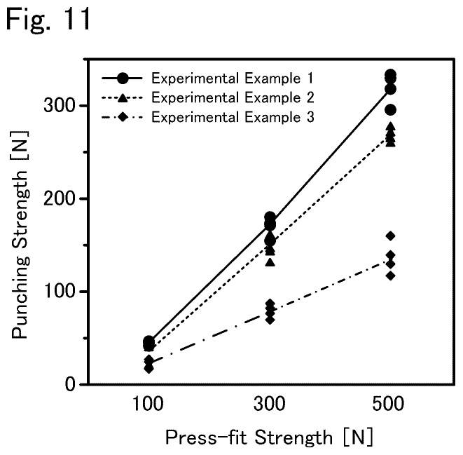

For Experimental Examples 1 to 3, the relationship between press-fit strength and punching strength was summarized in FIG. 11 and Table 1. As shown in FIG. 11 and Table 1, in any press-fit strength, the larger the value of α-θ, the greater the punching strength, and plug drop-out was suppressed. Further, the larger the value of α-θ, the higher the effect of increasing punching strength by increasing the press-fit strength, and plug drop-out was further suppressed. In particular, in Experimental Examples 1 and 2, a punching strength of 150 N or more could be achieved at a press-fit strength of 300 N, and a punching strength of 250 N or more could be achieved at a press-fit strength of 500 N, significantly suppressing plug drop-out. Moreover, in Experimental Examples 1 and 2, when the plug was press-fitted at 300 N, a punching strength of 3.5 times or more that at 100 N was achieved; and when the plug was press-fitted at 500 N, a punching strength of 7 times or more that at 100 N was achieved.

TABLE 1

| | | | | Punching Strength for each Press-fit Strength [N] | | | |
|---|---|---|---|---|---|---|---|
| | Inclination | Inclination | | | Press-Fit | Press-Fit | Press-Fit |
| | Angle θ | Angle | θ − α | | Strength | Strength | Strength |
| | [°] | [°] | [°] | | 100N | 300N | 500N |
| Experimental | 85.00 | 85.10 | 0.10 | min | 40.0 | 154.7 | 295.1 |
| Example 1 | | | | max | 46.8 | 179.6 | 333.0 |
| | | | | average | 43.0 | 171.2 | 318.0 |
| Experimental | 85.00 | 85.05 | 0.05 | min | 20.1 | 130.5 | 260.3 |
| Example 2 | | | | max | 44.9 | 170.4 | 277.2 |
| | | | | average | 36.0 | 150.5 | 267.1 |
| Experimental | 85.00 | 85.00 | 0.00 | min | 17.6 | 69.5 | 116.8 |
| Example 3 | | | | max | 26.5 | 86.1 | 159.4 |
| | | | | average | 22.6 | 77.1 | 134.8 |

What is claimed is:

1. A member for a semiconductor manufacturing apparatus comprising:
a ceramic plate having on its upper surface at least one of a wafer placement surface or a focus-ring placement surface;
a plug-receiving hole penetrating the ceramic plate in an up-down direction and having a tapered inner peripheral surface whose lower side narrows; and
a plug fitted in the plug-receiving hole, the plug having a tapered outer peripheral surface whose lower side narrows and allowing gas to flow in the up-down direction;
wherein an outer peripheral surface of the plug is steeper than an inner peripheral surface of the plug-receiving hole.

2. The member for a semiconductor manufacturing apparatus according to claim 1,
wherein a difference between an inclination angle α of the outer peripheral surface of the plug and an inclination angle θ of the inner peripheral surface of the plug-receiving hole is 0.2° or less.

3. The member for a semiconductor manufacturing apparatus according to claim 1,
wherein a difference between an inclination angle α of the outer peripheral surface of the plug and an inclination angle θ of the inner peripheral surface of the plug-receiving hole is 0.05° or more and 0.10° or less.

4. The member for a semiconductor manufacturing apparatus according to claim 1,
wherein an inclination angle θ of the inner peripheral surface of the plug-receiving hole is 70° or more and less than 88°.

5. The member for a semiconductor manufacturing apparatus according to claim 1,
wherein an extraction strength required to pull the plug out toward the wafer placement surface side is 150 N or more.

6. A member for a semiconductor manufacturing apparatus according to claim 1,
further comprising a conductive base plate bonded to a lower surface of the ceramic plate and provided with a gas supply passage communicating with the plug-receiving hole.

7. The member for a semiconductor manufacturing apparatus according to claim 1,
wherein the ceramic plate has an embedded electrode.

8. The member for a semiconductor manufacturing apparatus according to claim 1,
wherein the plug is press-fitted into the plug-receiving hole.

9. The member for a semiconductor manufacturing apparatus according to claim 1,
excluding those where the plug and the plug receiving hole are adhered with an adhesive layer.
